(19) United States
(12) Patent Application Publication
(10) Pub. No.: US 2024/0204093 A1
(43) Pub. Date: Jun. 20, 2024

(54) SEMICONDUCTOR DEVICE

(71) Applicant: SONY SEMICONDUCTOR SOLUTIONS CORPORATION, KANAGAWA (JP)

(72) Inventors: SHINYA MORITA, KANAGAWA (JP); ATSUSHI KURANOUCHI, KANAGAWA (JP); NAOKI KAKOIYAMA, KANAGAWA (JP)

(21) Appl. No.: 18/555,754

(22) PCT Filed: Feb. 8, 2022
(86) PCT No.: PCT/JP2022/004902

§ 371 Date: Oct. 17, 2023

(30) Foreign Application Priority Data
Apr. 30, 2021 (JP) 2021-077976

(51) Int. Cl. H01L 29/778; H01L 29/10

(52) U.S. Cl. CPC H01L 29/7786; H01L 29/1041

(57) ABSTRACT

A semiconductor device according to an embodiment of the present disclosure includes a channel layer and a barrier layer in this order on a substrate. The semiconductor device further includes a gate electrode, a source electrode, and a drain electrode that are formed on the substrate via the channel layer and the barrier layer. The gate electrode, the source electrode, and the drain electrode extend in a first direction. The channel layer or the barrier layer has a plurality of non-conductive regions formed at positions opposed to the gate electrode and arranged side by side, with a predetermined interval interposed therebetween, in an extending direction of the gate electrode. The non-conductive regions inhibit a current from flowing to the channel layer.

### TECHNICAL FIELD

The present disclosure relates to a semiconductor device.

### BACKGROUND ART

In a fifth-generation mobile communication system (5G), the use of a millimeter-wave-band signal is envisaged. In a millimeter wave band in which spatial attenuation is large, high power output is necessary, and a high output, high frequency semiconductor device is necessary. Examples of the high output, high frequency semiconductor device include a power amplifier and an RF switch (see, for example, Patent Literature 1).

### CITATION LIST

### Patent Literature

Patent Literature 1: Japanese Unexamined Patent Application Publication No. 2017-162958

### SUMMARY OF THE INVENTION

Incidentally, in a high output, high frequency semiconductor device, a heat generation due to Joule heat becomes a problem. As a temperature of a channel increases, an electrical resistance of the channel and peripheral wiring lines increases, and device characteristics deteriorate. In particular, in a case where the channels are densely packed, suppressing a concentration of the heat generation leads to a decrease in a maximum temperature. Therefore, it is desirable to provide a semiconductor device that makes it possible to suppress a concentration of a heat generation.

A semiconductor device according to a first embodiment of the present disclosure includes a channel layer and a barrier layer in this order on a substrate. The semiconductor device further includes a gate electrode, a source electrode, and a drain electrode that are formed on the substrate via the channel layer and the barrier layer. The gate electrode, the source electrode, and the drain electrode extend in a first direction. The channel layer or the barrier layer has a plurality of non-conductive regions formed at positions opposed to the gate electrode and arranged side by side, with a predetermined interval interposed therebetween, in an extending direction of the gate electrode. The non-conductive regions inhibit a current from flowing to the channel layer.

A semiconductor device according to a second embodiment of the present disclosure includes a channel layer and a barrier layer provided in this order on a substrate. The semiconductor device further includes a plurality of gate electrodes, a plurality of source electrodes, and a plurality of drain electrodes that are formed on the substrate via the channel layer and the barrier layer. Each of the gate electrodes, each of the source electrodes, and each of the drain electrodes extend in a first direction. The plurality of source electrodes and the plurality of drain electrodes are alternately arranged in a second direction intersecting the first direction. The plurality of gate electrodes is arranged one by one between the source electrode and the drain electrode. The channel layer or the barrier layer has a plurality of non-conductive regions formed at positions opposed to the respective gate electrodes and arranged side by side, with a predetermined interval interposed therebetween, in an extending direction of the gate electrodes. The non-conductive regions inhibit a current from flowing to the channel layer.

In the semiconductor device according to the first embodiment or the second embodiment of the present disclosure, in the channel layer or the barrier layer, the plurality of non-conductive regions formed side by side, with the predetermined interval interposed therebetween, in the extending direction of the gate electrode is provided at the positions opposed to the gate electrode. As a result, it is possible to reduce a current density in the extending direction of the gate electrode as compared with a case where the non-conductive regions are not provided.

### BRIEF DESCRIPTION OF THE DRAWINGS

FIG. 1 is a diagram illustrating a planar configuration example of a semiconductor device according to a first embodiment of the present disclosure.

FIG. 2 is a diagram illustrating an exemplary cross-sectional configuration of the semiconductor device of FIG. 1 along a A-A line.

FIG. 3 is a diagram illustrating an exemplary cross-sectional configuration of the semiconductor device of FIG. 1 along a B-B line.

FIG. 4 is a diagram illustrating an exemplary cross-sectional configuration of the semiconductor device of FIG. 1 along a C-C line.

FIG. 5 is a diagram illustrating a planar configuration example of a semiconductor device according to a second embodiment of the present disclosure.

FIG. 6 is a diagram illustrating an exemplary cross-sectional configuration of the semiconductor device of FIG. 5 along a A-A line.

FIG. 7 is a diagram illustrating an exemplary cross-sectional configuration of the semiconductor device of FIG. 5 along a B-B line.

FIG. 8 is a diagram illustrating an exemplary cross-sectional configuration of the semiconductor device of FIG. 5 along a C-C line.

FIG. 9 is a diagram illustrating a modification example of the cross-sectional configuration of FIG. 6.

FIG. 10 is a diagram illustrating a modification example of the cross-sectional configuration of FIG. 8.

FIG. 11 is a diagram illustrating a modification example of the cross-sectional configuration of FIG. 6.

FIG. 12 is a diagram illustrating a modification example of the cross-sectional configuration of FIG. 8.

FIG. 13 is a diagram illustrating a modification example of the cross-sectional configuration of FIG. 6.

FIG. 14 is a diagram illustrating a modification example of the cross-sectional configuration of FIG. 8.

FIG. 15 is a diagram illustrating a modification example of the planar configuration of FIG. 1.

FIG. 16 is a diagram illustrating a modification example of the cross-sectional configuration of FIG. 2.

FIG. 17 is a diagram illustrating a modification example of the cross-sectional configuration of FIG. 3.

FIG. 18 is a diagram illustrating a modification example of the cross-sectional configuration of FIG. 4.

FIG. 19 is a diagram illustrating a modification example of the planar configuration of FIG. 2.

FIG. 20 is a diagram illustrating a modification example of the cross-sectional configuration of FIG. 3.

FIG. 21 is a diagram illustrating a modification example of the cross-sectional configuration of FIG. 4.

FIG. 22 is a diagram illustrating a planar configuration example of a semiconductor device according to a third embodiment of the present disclosure.

FIG. 23 is a diagram illustrating a modification example of the planar configuration of FIG. 22.

FIG. 24 is a diagram illustrating a modification example of the planar configuration of FIG. 22.

FIG. 25 is a diagram illustrating a modification example of the planar configuration of FIG. 22.

FIG. 26 is a diagram illustrating an example of a high-frequency module to which the semiconductor device of any of FIGS. 1 to 25 is applied.

FIG. 27 is a diagram illustrating an example of a wireless communication device to which the semiconductor device of any of FIGS. 1 to 25 is applied.

### MODES FOR CARRYING OUT THE INVENTION

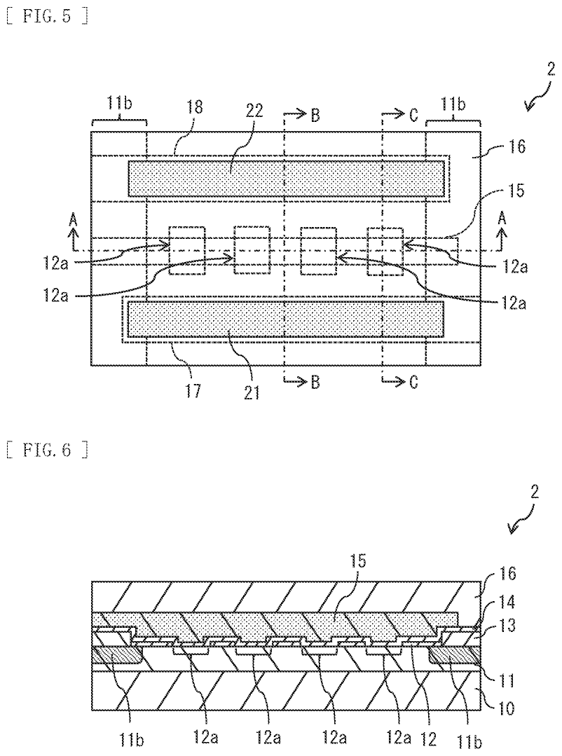

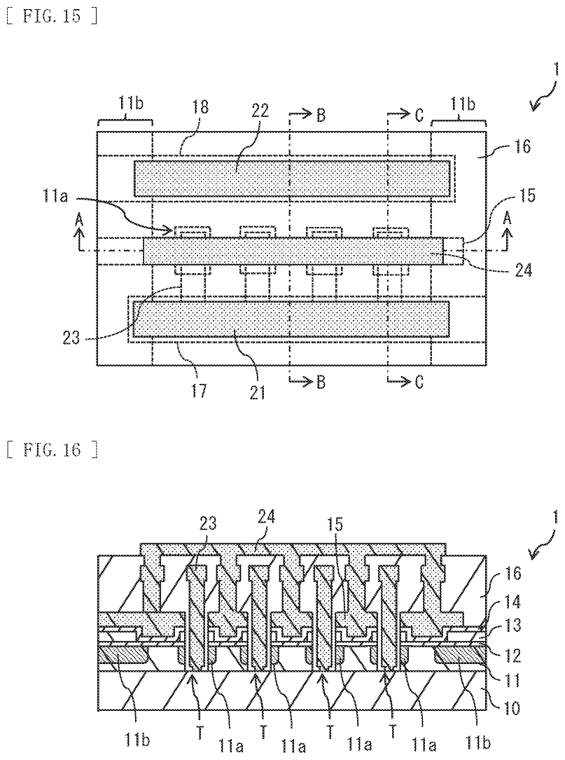

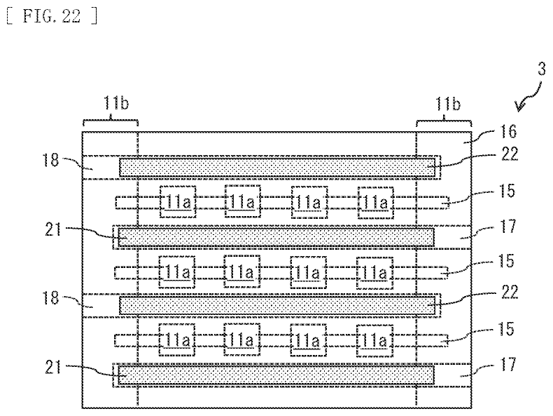

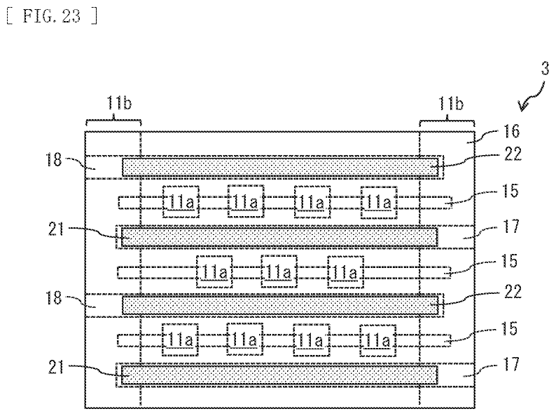

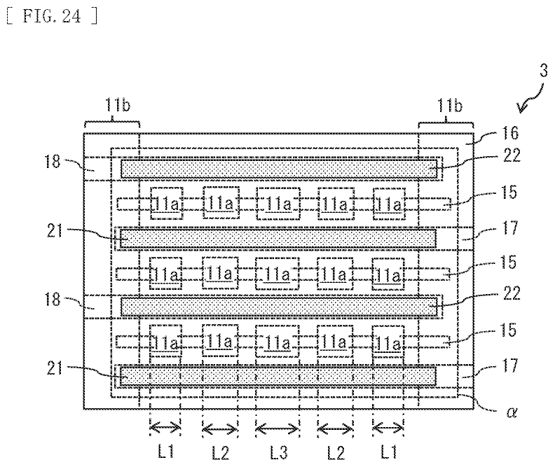

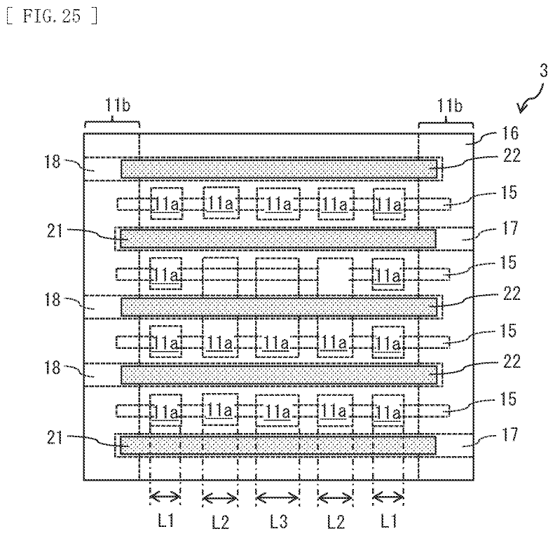

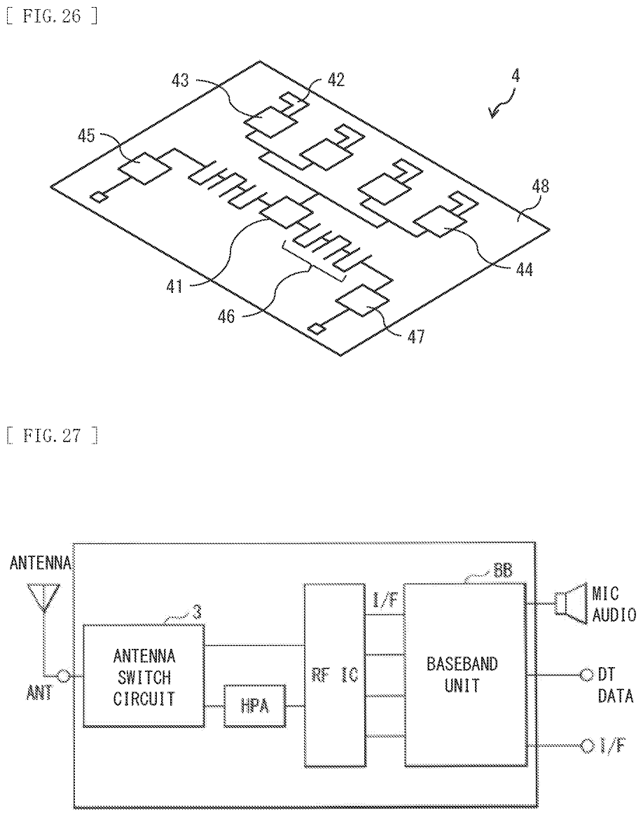

Hereinafter, an embodiment of the present disclosure is described in detail with reference to the drawings. The following description is a specific example of the present disclosure, but the present disclosure is not limited to the following embodiment. Moreover, the present disclosure does not limit the disposition, dimensions, dimension ratios, and the like of respective components illustrated in the drawings thereto. It is to be noted that description is given in the following order.
1. Background
2. First Embodiment (Semiconductor Device) . . . FIG. 1 to FIG. 4
3. Second Embodiment (Semiconductor Device) . . . FIG. 5 to FIG. 8
4. Modification Examples of Second Embodiment (Semiconductor Device) . . . FIG. 9 to FIG. 14
5. Modification Examples of Second Embodiment (Semiconductor Device) . . . FIG. 15 to FIG. 21
6. Third Embodiment (Semiconductor Device) . . . FIG. 22
7. Modification Examples of Third Embodiment (Semiconductor Device) . . . FIG. 23 to FIG. 25
8. Applicable Examples (High-Frequency Module and Wireless Communication Device) . . . FIG. 26 and FIG. 27

### 1. BACKGROUND

In a fifth-generation mobile communication system (5G), the use of a millimeter-wave-band signal is envisaged. In a millimeter wave band in which spatial attenuation is large, high power output is necessary, and a high output, high frequency semiconductor device is necessary. Examples of the high output, high frequency semiconductor device include a power amplifier and an RF switch.

GaN has characteristics such as a high breakdown voltage, a high temperature operation, and a high saturation drift. Two-dimensional electron gas (2DEG) formed in a GaN heterojunction is characterized by a high mobility and a high sheet electron density. These characteristics enable a high-speed and high-withstand voltage operation with low resistivity in a high electron mobility transistor (High Electron Mobility Transistor: HEMT) using the GaN heterojunction. Therefore, the high electron mobility transistor using the GaN heterojunction is expected to be applied to a high output, high frequency semiconductor device.

Incidentally, because a large current flows through a channel in a power amplifier, a heat generation due to Joule heat becomes a problem. As a temperature of the channel increases, an electrical resistance of the channel and peripheral wiring lines increases, and the characteristics of the power amplifier deteriorate. As a method of suppressing the temperature increase of the channel, it is conceivable to promote an exhaust heat to the outside of the device. However, in a portable terminal in which the use of the GaN-based HEMT is expected, a size-restriction is large, and it is difficult to provide an adequate heat exhaust mechanism.

As another method of suppressing the temperature increase of the channel, it is also effective to reduce a density of the channel. In many cases, a multi-finger structure in which a plurality of gates is arranged in parallel is adopted as an FET for the power amplifier. In a case where a total gate width is constant, it is possible to reduce a gate width per unit and to suppress a concentration of heat generation by increasing the number of fingers, thereby reducing the maximum temperature. In addition, increasing an interval between the fingers makes it possible to further reduce the maximum temperature.

On the other hand, increasing the number of fingers and increasing the finger interval can lead to an increase in the device area. In a case where the number of fingers is increased, the wiring area associated with the channel also increases; therefore, the device area increases when the number of fingers is increased even if a total gate length is the same. In addition, because an aspect in vertical and horizontal directions becomes large, a flexibility of layout in IC is also reduced. Therefore, in the following, in a semiconductor device having the multi-finger structure, embodiments of a semiconductor device that makes it possible to suppress the concentration of the heat generation while suppressing the increase in size, a semiconductor module and an electronic apparatus including such a semiconductor device will be described.

### 2. FIRST EMBODIMENT

### Configuration

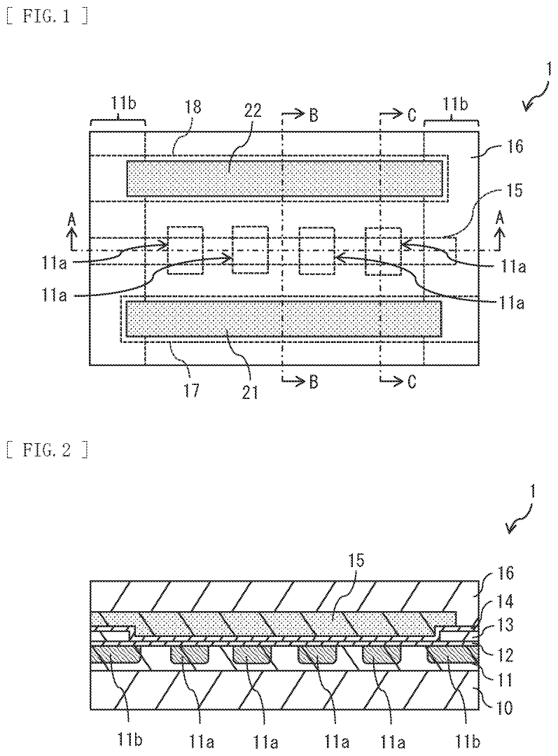

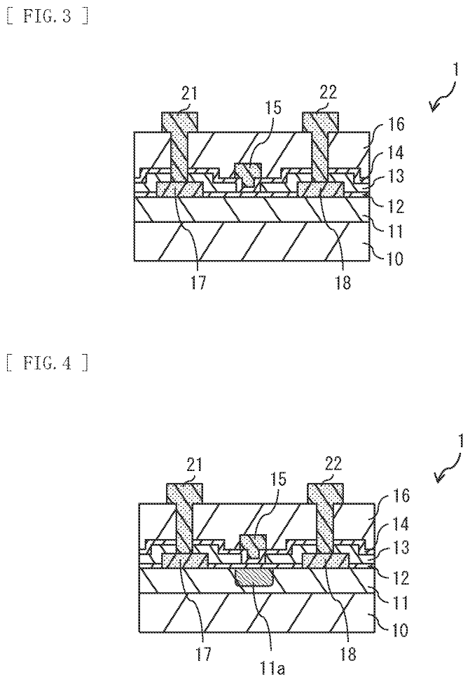

Next, a semiconductor device 1 according to a first embodiment of the present disclosure will be described. FIG. 1 illustrates a planar configuration example of the semiconductor device 1 according to the present embodiment. FIG. 2 illustrates an exemplary cross-sectional configuration of the semiconductor device 1 of FIG. 1 along a A-A line. FIG. 3 illustrates an exemplary cross-sectional configuration of the semiconductor device 1 of FIG. 1 along a B-B line. FIG. 4 illustrates an exemplary cross-sectional configuration of the semiconductor device 1 of FIG. 1 along a C-C line.

The semiconductor device 1 includes a high electron mobility transistor using a heterojunction of Al_{1-x-y}GaₓIn_{y}N (0≤x≤1, 0≤y<1)/GaN. In the semiconductor device 1, the high electron mobility transistor has, for example, a multi-finger structure in which a plurality of gates is arranged in parallel. For example, a gate electrode 15, a source electrode 17, and a drain electrode 18 of the high electron mobility transistor extend in a first direction (a left-right direction in the paper surface of FIG. 1). Further, for example, the source electrode 17 and the drain electrode 18 are so disposed as to oppose each other in a second direction intersecting the first direction (a vertical direction in the paper surface of FIG. 1) via the gate electrode 15.

The gate electrode 15 has a gate operating section in contact with a channel layer 11 via a gate insulating film 14 and a barrier layer 12. The gate operating section controls a current to flow in a portion, of the channel layer 11, immediately below the gate operating section by applying a predetermined voltage to the gate electrode 15. A plurality of impurity regions 11a is so formed on a surface, of the channel layer 11, on the gate operating section side as to cross the gate operating section in the second direction (the vertical direction in the paper surface of FIG. 1). The plurality of impurity regions 11a is arranged side by side in the first direction (the left-right direction in the paper surface of FIG. 1) at predetermined intervals. The impurity region 11a is, for example, a non-active region in which a resistivity of the channel layer 11 is increased by ion-implantation of boron or the like. In the channel layer 11, a region immediately below the gate operating section and where the impurity region 11a is not formed is an active region. Incidentally, in the channel layer 11, an impurity region 11b, which is a non-active region having a high resistance by, for example, ion-implantation of boron, may be formed in a region opposed to both end portions of the gate electrode 15, the source electrode 17, and the drain electrode 18 in a plan view. The impurity region 11b serves as an element separation region. In the active region, a two-dimensional electron gas layer serving as a channel is generated. On the other hand, in the impurity region 11a and 11b which are the non-active regions, the two-dimensional electron gas layer is not generated. As described above, in the present embodiment, the active region (the channel region) is divided into a plurality of regions by the plurality of impurity regions 11a, thereby achieving the multi-finger structure. For example, the impurity regions 11a and 11b are collectively formed in the same process in the manufacturing process.

The semiconductor device 1 includes, for example, the channel layer 11 and the barrier layer 12 in this order on a substrate 10. The semiconductor device 1 further includes, for example, an insulating layer 13 having an opening (hereinafter, referred to as a “gate opening”) at a position where the above-described gate operating section is formed on the barrier layer 12. The gate opening extends in the first direction (the left-right direction in the paper surface of FIG. 1). The semiconductor device 1 further includes, for example, the gate insulating film 14 so formed as to be in contact with the barrier layer 12 exposed on a bottom surface of the gate opening of the barrier layer 12. The gate insulating film 14 is a conformal layer formed along the bottom surface and an inner wall of the gate opening of the barrier layer 12 and a surface of the insulating layer 13. The semiconductor device 1 further includes, for example, the gate electrode 15 so formed as to fill the gate opening of the barrier layer 12. The gate electrode 15 extends in the first direction (the left-right direction in the paper surface of FIG. 1). The semiconductor device 1 includes the gate electrode 15 on the substrate 10 via the channel layer 11 and the barrier layer 12.

In the barrier layer 12, in addition to the gate opening, a pair of openings (hereinafter, referred to as a “source opening” and a “drain opening”) extending in the first direction (the left-right direction in the paper surface of FIG. 1) are formed at positions so opposed to each other as to sandwich the gate opening. The channel layer 11 is exposed on the bottom surface of the source opening and the drain opening.

The semiconductor device 1 further includes, for example, the source electrode 17 that is ohmically bonded to the channel layer 11 exposed on the bottom surface of the source opening, and the drain electrode 18 that is ohmically bonded to the channel layer 11 exposed on the bottom surface of the drain opening. The source electrode 17 and the drain electrode 18 extend in the first direction (the left-right direction in the paper surface of FIG. 1). The semiconductor device 1 includes the source electrode 17 and the drain electrode 18 on the substrate 10 via the channel layer 11 and the barrier layer 12.

Surfaces of the source electrode 17 and the drain electrode 18 are covered with the insulating layer 13. In the insulating layer 13 and the gate insulating film 14, openings (hereinafter, referred to as “lead-out electrode openings”) are respectively formed at a position opposed to the source electrode 17 and a position opposed to the drain electrode 18. The source electrode 17 is exposed on a bottom surface of one of the lead-out electrode openings. The drain electrode 18 is exposed on a bottom surface of the other lead-out electrode opening. The semiconductor device 1 further includes, for example, an insulating layer 16 formed in contact with surfaces of the gate electrode 15 and the gate insulating film 14. An upper surface of the insulating layer 16 is a planarized flat surface as compared to the surfaces of the gate electrode 15 and the gate insulating film 14. In the insulating layer 16, an opening communicating with the lead-out electrode opening is formed. The semiconductor device 1 further includes, for example, lead-out electrodes 21 and 22 so formed as to fill the lead-out electrode opening and the opening of the insulating layer 16. The lead-out electrode 21 is in contact with the source electrode 17. The lead-out electrode 22 is in contact with the drain electrode 18.

The substrate 10 includes, for example, GaN. In a case where a buffer layer that controls a lattice parameter is provided between the substrate 10 and the channel layer 11, the substrate 10 may include, for example, Si, SiC, sapphire, or the like. In this case, for example, the buffer layer is configured by a compound semiconductor such as AlN, AlGaN, or GaN.

The channel layer 11 is a layer in which a channel of a high electron mobility transistor is formed. The active region (the channel region) in the channel layer 11 is a region in which carriers are accumulated by polarization with the barrier layer 12. The channel layer 11 includes a compound semiconductor material in which the carriers are easily accumulated by the polarization with the barrier layer 12. Examples of such a compound semiconductor material include GaN. The channel layer 11 may include an undoped compound semiconductor material. In this case, an impurity scattering of the carriers in the channel layer 11 is suppressed, and a carrier movement with high mobility is achieved. The channel layer 11 forms a two-dimensional electron gas layer serving as a channel at an interface of the channel layer 11 in contact with the barrier layer 12 by heterojunction of the channel layer 11 and the barrier layer 12 that include different compound semiconductor materials.

The barrier layer 12 includes a compound semiconductor material in which the carriers are accumulated in the channel layer 11 by the polarization with the channel layer 11. Examples of such a compound semiconductor material include Al_{1-a-b}GaₐIn_{b}N (0≤a<1, 0≤b<1). The barrier layer 12 may include an undoped compound semiconductor material. In this case, an impurity scattering of the carriers in the channel layer 11 is suppressed, and the carrier movement with high mobility is achieved.

The insulating layer 13, the gate insulating film 14, and the insulating layer 16 include, for example, aluminum oxide (Al₂O₃), silicon oxide (SiO₂), or silicon nitride (SiN). The gate electrode 15 has a structure in which, for example, nickel (Ni) and gold (Au) are stacked in this order from the substrate 10 side. The source electrode 17 and the drain electrode 18 are configured to be ohmically bonded to the channel layer 11 by, for example, laminating titanium (Ti), aluminum (Al), nickel (Ni), and gold (Au) in this order from the substrate 10 side.

### Effects

Next, effects of the semiconductor device 1 will be described.

In the semiconductor device 1, when a predetermined voltage is applied to the gate electrode 15, the two-dimensional electron gas layer is generated in a portion, of the channel layer 11, where the impurity regions 11a are not formed. As a result, a portion, of the channel layer 11, where the impurity regions 11a are not formed becomes the active region (the channel region). As a result, a current flows from the drain electrode 18 to the source electrode 17 through the active region (the channel region) of the channel layer 11. Therefore, the portion, of the channel layer 11, where the impurity region 11a is not formed operates as a normal HEMT.

On the other hand, a portion, of the channel layer 11, where the impurity region 11a is formed becomes a non-conductive region where no current flows constantly (a non-conductive region where a current flowing to the channel layer 11 is inhibited). As described above, by forming the non-conductive region at a portion, of the channel layer 11, opposed to the gate operating section, it is possible to reduce a current density in the first direction (the left-right direction in the paper surface of FIG. 1) as compared with a case where the non-conductive region is not provided. As a result, the concentration of heat generated by the current is suppressed, making it possible to lower the maximum temperature in the channel. Therefore, it is possible to suppress a degradation of device characteristics.

Further, in the present embodiment, by forming the non-conductive region in the portion, of the channel layer 11, opposed to the gate operating section, it is possible to suppress the concentration of heat generated by the current without increasing the channel width, making it possible to lower the maximum temperature in the channel. Accordingly, it is possible to suppress the concentration of heat generation while suppressing an increase in the size of the semiconductor device 1.

### 3. SECOND EMBODIMENT

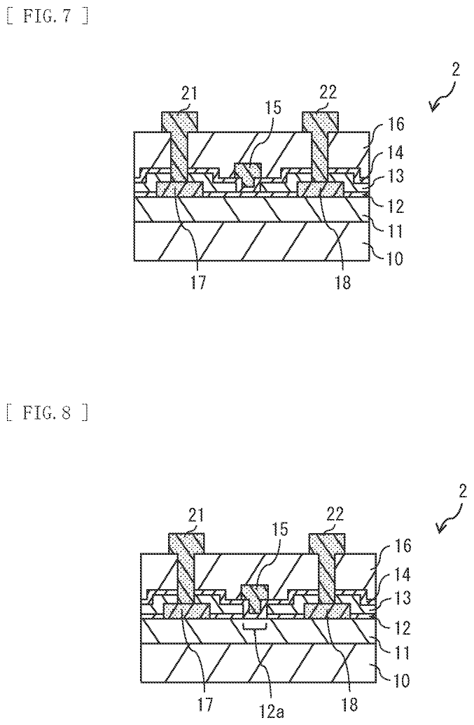

Next, a semiconductor device 2 according to a second embodiment will be described. FIG. 5 illustrates a planar configuration example of the semiconductor device 2 according to the present embodiment. FIG. 6 illustrates an exemplary cross-sectional configuration of the semiconductor device 2 of FIG. 5 along A-A line. FIG. 7 illustrates an exemplary cross-sectional configuration of the semiconductor device 2 of FIG. 5 along B-B line. FIG. 8 illustrates an exemplary cross-sectional configuration of the semiconductor device 2 of FIG. 5 along C-C line.

In the semiconductor device 2, a plurality of openings 12a is provided in the barrier layer 12 in place of the impurity region 11a in the semiconductor device 1, so that the plurality of non-conductive regions is provided in the portion, of the channel layer 11, opposed to the gate operating section. In other words, the channel layer 11 has the opening 12a that penetrates the channel layer 11 as the non-conductive region. Even in such a case, as in the case of the semiconductor device 1, it is possible to reduce the current density in the first direction (the left-right direction in the paper surface of FIG. 1) as compared with a case where the non-conductive region is not provided. As a result, the concentration of heat generated by the current is suppressed, making it possible to lower the maximum temperature in the channel. Therefore, it is possible to suppress the degradation of device characteristics.

Further, in the present embodiment, by forming the non-conductive region in the portion, of the channel layer 11, opposed to the gate operating section, it is possible to suppress the concentration of heat generated by the current without increasing the channel width, making it possible to lower the maximum temperature in the channel. Accordingly, it is possible to suppress the concentration of heat generation while suppressing an increase in the size of the semiconductor device 2.

### 4. MODIFICATION EXAMPLES OF SECOND EMBODIMENT

Next, modification examples of the semiconductor device 2 according to the second embodiment of the present disclosure will be described.

### Modification Example2-1

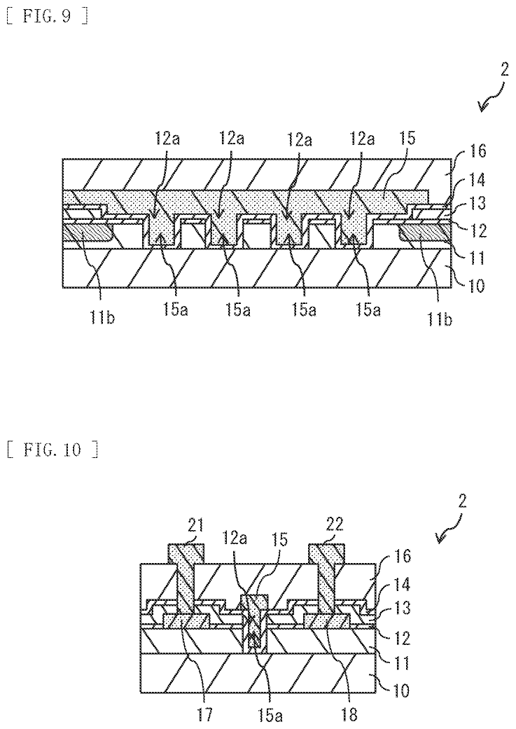

In the second embodiment, for example, as illustrated in FIGS. 9 and 10, the gate electrode 15 may have a columnar branch section 15a that penetrates the channel layer 11 through the opening 12a. At this time, the branch section 15a is in contact with the substrate 10 and the channel layers 11 via, for example, the gate insulating film 14, and is isolated from the substrate 10. FIG. 9 illustrates a modification example of the cross-sectional configuration of FIG. 6. FIG. 10 illustrates a modification example of the cross-sectional configuration of FIG. 8.

At least the branch section 15a of the gate electrode 15 may include a material having a thermal conductivity higher than that of the channel layer 11. Accordingly, it is possible to allow the heat generated in the channel to be propagated to the substrate 10 via the gate electrode 15. As a result, because the heat dissipation property of the semiconductor device 2 is improved, it is possible to lower the maximum temperature in the channel. Therefore, it is possible to suppress the degradation of device characteristics.

### Modification Example2-2

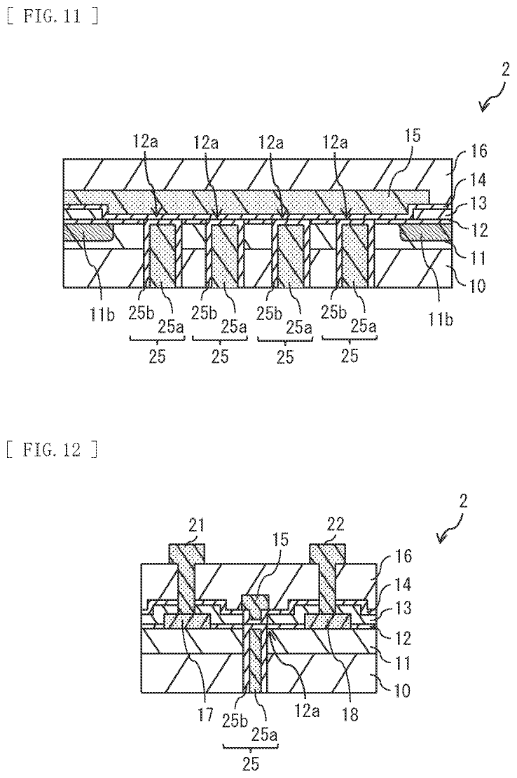

In the second embodiment, for example, as illustrated in FIGS. 11 and 12, the semiconductor device 2 may further include a non-conductive section 25 that reaches the opening 12a of the barrier layer 12 from a back surface of the substrate 10. FIG. 11 illustrates a modification example of the cross-sectional configuration of FIG. 6. FIG. 12 illustrates a modification example of the cross-sectional configuration of FIG. 8.

The non-conductive section 25 includes, for example, from the back surface of the substrate 10, an insulating layer 25b formed along an inner surface of a recess reaching the opening 12a of the barrier layer 12, and a heat transfer section 25a so formed as to fill the recess. The non-conductive section 25 is a non-conductive region in which a current does not flow constantly (a non-conductive section in which a current is inhibited from flowing). The insulating layers 25b includes, for example, aluminum oxide (Al₂O₃), silicon oxide (SiO₂), or silicon nitride (SiN). The heat transfer section 25a may include, for example, a material having a thermal conductivity high than that of the channel layer 11. Accordingly, it is possible to allow the heat generated in the channel to be propagated to the substrate 10 through the non-conductive section 25. As a result, the heat dissipation property of the semiconductor device 2 is improved, making it possible to lower the maximum temperature in the channel. Therefore, it is possible to suppress the degradation of device characteristics.

In addition, by providing the plurality of non-conductive sections 25 in the barrier layer 12 and the channel layer 11 instead of the impurity region 11a, the plurality of non-conductive regions is provided in the channel layer 11 at positions opposed to the gate operating section. Even in such a case, as in a case of the semiconductor device 2, it is possible to reduce the current density in the first direction (the left-right direction in the paper surface of FIG. 1) as compared with a case where the non-conductive region is not provided. As a result, the concentration of heat generated by the current is suppressed, making it possible to lower the maximum temperature in the channel. Therefore, it is possible to suppress the degradation of device characteristics.

### Modification Example2-3

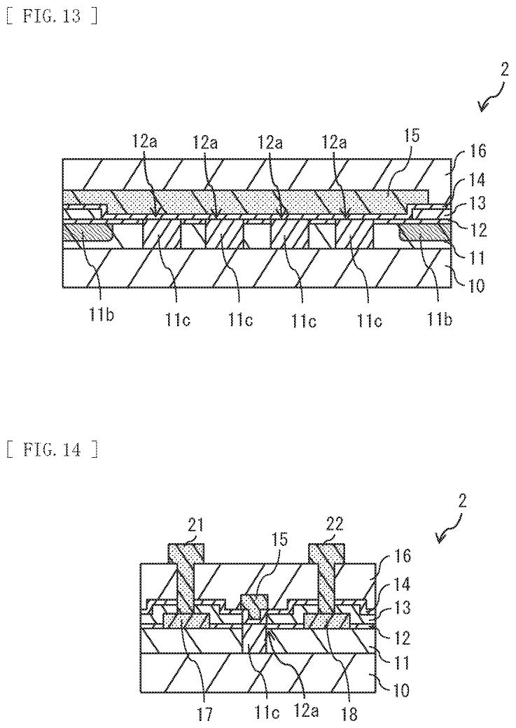

In the second embodiment, for example, as illustrated in FIGS. 13 and 14, the semiconductor device 2 may further include an insulating section 11c that penetrates the channel layer 11 from the opening 12a of the barrier layer 12. FIG. 13 illustrates a modification example of the cross-sectional configuration of FIG. 6. FIG. 14 illustrates a modification example of the cross-sectional configuration of FIG. 8.

The insulating section 11c includes, for example, aluminum oxide (Al₂O₃), silicon oxide (SiO₂), or silicon nitride (SiN). Providing, in place of the impurity region 11a, a plurality of insulating sections 11c in the barrier layer 12 and the channel layer 11 allows for a configuration in which the plurality of non-conductive regions (the non-conductive regions that inhibit the current flow) is provided in the channel layer 11 at positions opposed to the gate operating section. Even in such a case, as in a case of the semiconductor device 2, it is possible to reduce the current density in the first direction (the left-right direction in the paper surface of FIG. 1) as compared with a case where the non-conductive region is not provided. As a result, the concentration of heat generated by the current is suppressed, making it possible to suppress the maximum temperature in the channel. Therefore, it is possible to suppress the degradation of device characteristics.

### 5. MODIFICATION EXAMPLES OF FIRST EMBODIMENT

Next, modification examples of the first embodiment are described.

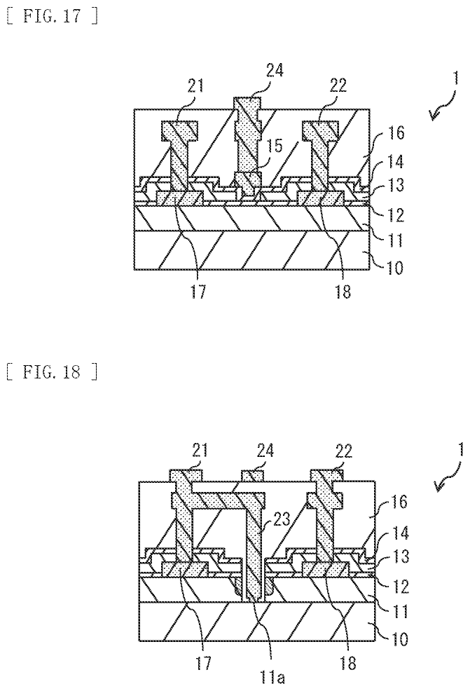

FIG. 15 illustrates a planar configuration example of the semiconductor device 1 according to the present modification example. FIG. 16 illustrates an exemplary cross-sectional configuration of the semiconductor device 1 of FIG. 15 along A-A line. FIG. 17 illustrates an exemplary cross-sectional configuration of the semiconductor device 1 of FIG. 15 along B-B line. FIG. 18 illustrates an exemplary cross-sectional configuration of the semiconductor device 1 of FIG. 15 along C-C line.

In this modification example, a trench T is formed in each of the impurity regions 11a, and each trench T penetrates the impurity region 11a, the barrier layer 12, the insulating layer 13, and the gate insulating film. An inner peripheral surface of each trench T is covered with the insulating layer 16. Metal sections 23 that include a metal material (for example, Cu, Au, or the like) having a higher thermal conductivity than a material of the channel layer 11 are inserted into the respective trenches T. The metal section 23 is in contact with the substrate 10 exposed on a bottom surface of the trench T. The metal section 23 is further coupled to, for example, the source electrode 17 or the lead-out electrode 21.

In the present modification example, the trench T and the metal section 23 are provided for each of the impurity regions 11a, so that the gate electrode 15 is divided for each channel region. That is, the gate electrode 15 is configured by a plurality of partial gate electrodes provided one by one for each channel region. In the present modification example, the plurality of partial gate electrodes is coupled to each other by a connection wiring line 24 via a through-hole provided in the insulating layer 16.

As described above, in the present modification example, the metal sections 23 penetrate the respective impurity regions 11a, and are in contact with the substrate 10, the source electrode 17, or the lead-out electrode 21. As a result, the heat generated in the channel region propagates to the substrate 10, the source electrode 17, or the lead-out electrode 21 via the respective metal sections 23, and is discharged to the outside. Therefore, as compared with a case where the metal section 23 is not provided, it is possible to reduce the current density in both the first direction (the left-right direction in the paper surface of FIG. 1) and the second direction (the vertical direction in the paper surface of FIG. 1). As a result, the concentration of heat generated by the current is suppressed, making it possible to lower the maximum temperature in the channel. Therefore, it is possible to suppress the degradation of device characteristics.

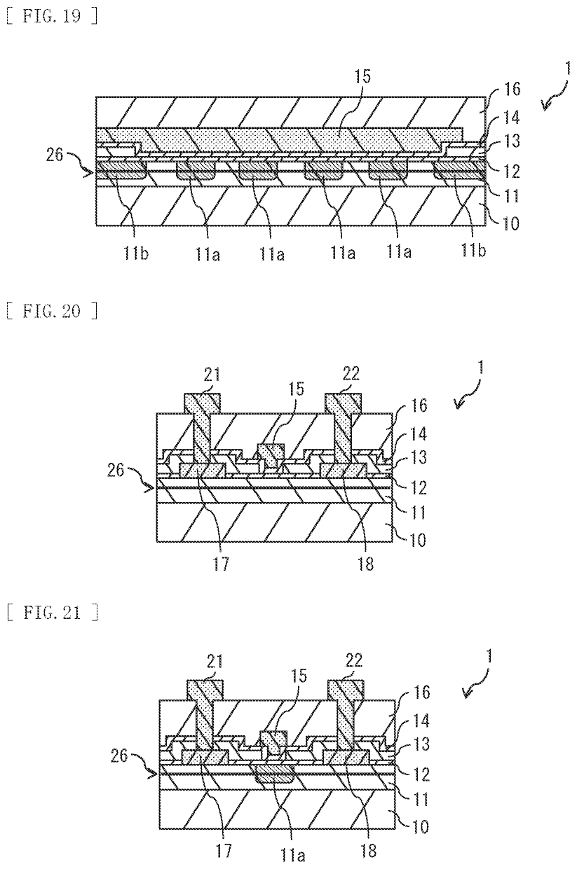

FIG. 19, FIG. 20, and FIG. 21 each illustrate a cross-sectional configuration example of the semiconductor device 1 according to the present modification example. FIG. 19 illustrates an exemplary cross-sectional configuration at a position corresponding to A-A line of FIG. 1. FIG. 20 illustrates an exemplary cross-sectional configuration at a position corresponding to B-B line of FIG. 1. FIG. 21 illustrates an exemplary cross-sectional configuration at a position corresponding to C-C line of FIG. 1.

In the present modification example, a back barrier layer 26 is provided in the channel layer 11. The back barrier layer 26 performs a quantum confinement on the two-dimensional electron gas (2DEG) formed in the channel layer 11. The back barrier layer 26 includes, for example, AlGaN or the like. A thermal conductivity of the back barrier layer 26 is low. Therefore, a thermal resistance at an interface of the back barrier layer 26 deteriorates the exhaust heat property. However, because the plurality of impurity regions 11a is provided in the channel layer 11, it is possible to lower the maximum temperature and to prevent the degradation of due to the heat generation.

### 6. THIRD EMBODIMENT

Next, a semiconductor device 3 according to a third embodiment of the present disclosure will be described. FIG. 22 illustrates a planar configuration example of the semiconductor device 3 according to the present embodiment.

The semiconductor device 3 corresponds to a device in which a plurality of high electron mobility transistors is provided in the semiconductor device 1 or 2. In the semiconductor device 3, each high electron mobility transistor has, for example, the multi-finger structure in which the plurality of gates is arranged in parallel. Furthermore, in two high electron mobility transistors adjacent to each other, the source electrode 17 or the drain electrode 18 is made common to each other.

The semiconductor device 3 includes, for example, the channel layer 11 and the barrier layer 12 in this order on the substrate 10. The semiconductor device 3 further includes, for example, a plurality of gate electrodes 15, a plurality of source electrodes 17, and a plurality of drain electrodes 18 on the substrate 10 via the channel layer 11 and the barrier layer 12. Each of the gate electrode 15, each of the source electrodes 17, and each of the drain electrodes 18 extend in the first direction (the left-right direction in the paper surface of FIG. 22). The plurality of source electrodes 17 and the plurality of drain electrodes 18 are alternately arranged in the second direction intersecting the first direction (the vertical direction in the paper surface of FIG. 22). Each of the plurality of gate electrodes 15 is disposed one by one between the source electrode 17 and the drain electrode 18.

In the present embodiment, the plurality of impurity regions 11a formed side by side with predetermined intervals in the extending direction of the gate electrode 15 is provided at positions opposed to the respective gate electrodes 15. The plurality of impurity regions 11a is arranged in a matrix in plan view, for example. Furthermore, in the channel layer 11, a plurality of regions (the active regions (the channel regions)) in which the impurity regions 11a are not formed are also arranged in a matrix in plan view. As a result, it is possible to reduce the current density in both the first direction and the second direction as compared with a case where the non-conductive region (the impurity region 11a) is not provided by forming the non-conductive region (the impurity region 11a) in the portion, of the channel layer 11, opposed to the gate operating section. As a result, the concentration of heat generated by the current is suppressed, making it possible to lower the maximum temperature in the channel. Therefore, it is possible to suppress the degradation of device characteristics.

### 7. MODIFICATION EXAMPLES OF THIRD EMBODIMENT

Next, modification examples of the semiconductor device 3 according to the third embodiment of the present disclosure will be described.

### Modification Example3-1

In the third embodiment, the plurality of impurity regions 11a may be alternately arranged in both a row direction and a column direction in a plan view, for example, as illustrated in FIG. 23. At this time, the plurality of impurity regions 11a is arranged at positions that are non-opposite to each other via the source electrode 17 or the drain electrode 18. In this case, as compared with the third embodiment, it is possible to increase a distance between two impurity regions 11a adjacent each other in the second direction. As a result, the concentration of heat generated by the current is suppressed, making it possible to lower the maximum temperature in the channel. Therefore, it is possible to suppress the degradation of device characteristics.

### Modification Example3-2

In the third embodiment, a region in which the plurality of impurity regions 11a is formed is denoted by u. For example, as illustrated in FIG. 24, the plurality of impurity regions 11a may be formed to be relatively wide in the second direction in a middle portion of the region a in the extending direction (the second direction) of the source electrode 17 and the drain electrode 18, and may be formed to be relatively narrow in the second direction at both end portions of the region a in the second direction. In this case, the width in the second direction of the impurity region 11a provided at both end portions of the region a in the second direction is defined as L1. In addition, the width in the second direction of the impurity region 11a provided in the middle of the region a is defined as L3. In addition, in the region u, the width in the second direction of the impurity region 11a provided between the impurity region 11a having the width L1 and the impurity region 11a having the width L3 is defined as L2. At this time, the widths L1, L2, and L3 satisfy the following expression.

L3>L2>L1

In this case, it is possible to reduce the current density in the second direction as compared with a case where all the impurity regions 11a are formed to have an equal size. As a result, the concentration of heat generated by the current is suppressed, making it possible to lower the maximum temperature in the channel. Therefore, it is possible to suppress the degradation of device characteristics.

### Modification Example3-3

In modification example 3-3, in the middle portion in the second direction, the plurality of impurity regions 11a may be formed not only directly below the gate electrode 15 but also directly below the drain electrode 18 or the source electrode 17 in the channel layer 11. At this time, the plurality of high-electron mobility transistors provided in the middle portion in the second direction may share one impurity region 11a with each other. In this case, it is possible to reduce the current density in both the first direction and the second direction as compared with a case where all the impurity regions 11a are formed directly below the gate electrode 15. As a result, the concentration of heat generated by the current is suppressed, making it possible to lower the maximum temperature in the channel. Therefore, it is possible to suppress the degradation of device characteristics.

### 8. APPLICATION EXAMPLES

### Application Example 1

Next, with reference to FIG. 26, a high-frequency module 4 to which any of the semiconductor devices 1, 2, and 3 according to the embodiments of the present disclosure and modification examples thereof is applied will be described. FIG. 26 is a perspective view of the high-frequency module 4.

The high-frequency module 4 includes, for example, an edge antenna 42, a driver 43, a phase adjustment circuit 44, a switch 41, a low-noise amplifier 45, a band-pass filter 46, and a power amplifier 47.

The high-frequency module 4 is an antenna-integrated module in which an edge antenna 42 formed in an array shape and front-end components including, for example, the switch 41, the low-noise amplifier 45, the band-pass filter 46, and the power amplifier 47 are integrally mounted as one module. Such a high-frequency module 4 may be used, for example, as a transceiver for communication. The transistor included in, for example, the switch 41, the low-noise amplifier 45, and the power amplifier 47 included in the high-frequency module 4 may be configured by, for example, the high-electron mobility transistor provided in any of the semiconductor devices 1, 2, and 3 according to the embodiments and the modification examples thereof of the present disclosure in order to increase a gain with respect to a high frequency.

### Application Example 2

FIG. 27 illustrates an example of a wireless communication device. The wireless communication device is, for example, a mobile telephone system having a multifunctional function such as voice, data communication, and LAN connection. The wireless communication device includes, for example, an antenna ANT, an antenna switch circuit 5, a high-power amplifier HPA, a high-frequency integrated circuit RFIC (Radio Frequency Integrated Circuit), a baseband unit BB, an audio output unit MIC, a data output unit DT, and an interface unit IF (for example, a wireless LAN (W-LAN: Wireless Local Area Network, a Bluetooth (registered trademark), etc.). The antenna switch circuit 5 includes the high electron mobility transistor provided in the semiconductor device 1 according to the embodiment of the present disclosure and the modification examples thereof. The high-frequency integrated circuit RFIC and the baseband unit BB are coupled by an interface unit IF.

In the wireless communication device, at the time of transmission, that is, in a case where a transmission signal is to be outputted from a transmission system of the wireless communication device to the antenna ANT, the transmission signal outputted from the baseband unit BB is outputted to the antenna ANT via the high-frequency integrated circuit RFIC, the high-power amplifier HPA, and the antenna switch circuit 5.

At the time of reception, that is, in a case where a signal received by the antenna ANT is to be inputted to a reception system of the wireless communication device, a reception signal is inputted to the baseband unit BB via the antenna switch circuit 5 and the high-frequency integrated circuit RFIC. A signal processed by the baseband unit BB is outputted from the audio output unit MIC, the data output unit DT, and an output unit such as the interface unit IF.

Although the present disclosure has been described with reference to the embodiments, modification examples, and application examples, the present disclosure is not limited to the above-described embodiments and the like, and various modifications are possible. It should be noted that the effects described in this specification are only exemplified. The effects of the present disclosure are not limited to the effects described herein. The present disclosure may have effects other than the effects described herein.

For example, the present disclosure may also be configured as follows.

(1)

A semiconductor device including:
a channel layer and a barrier layer provided in this order on a substrate; and
a gate electrode, a source electrode, and a drain electrode that are formed on the substrate via the channel layer and the barrier layer and extend in a first direction, in which
the channel layer or the barrier layer has a plurality of non-conductive regions formed at positions opposed to the gate electrode and arranged side by side, with a predetermined interval interposed therebetween, in an extending direction of the gate electrode, the non-conductive regions inhibiting a current from flowing to the channel layer.
   (2)

The semiconductor device according to (1), in which
the channel layer has the non-conductive regions, and
the non-conductive regions are formed by ion implantation into the channel layer.
   (3)

The semiconductor device according to (2), in which
the channel layer has an element separation region in a region, of the channel layer, opposed to both end portions of the gate electrode, the source electrode, and the drain electrode in a plan view, and
the non-conductive regions and the element separation region are collectively formed in the same process in a manufacturing process.
   (4)

The semiconductor device according to (2) or (3), further including a metal section that penetrates the non-conductive region and the barrier layer and is coupled to the source electrode.

(5)

The semiconductor device according to (1), in which
the barrier layer has the non-conductive region, and
the barrier layer has, as the non-conductive region, an opening that penetrates the barrier layer.
   (6)

The semiconductor device according to (5), in which the gate electrode has a branch section that penetrates the channel layer through the opening.

(7)

The semiconductor device according to (6), in which the branch section includes a material having a thermal conductivity higher than a thermal conductivity of the channel layer.

(8)

The semiconductor device according to (5), further including a non-conductive section that reaches the opening from a back surface of the substrate and inhibits the current from flowing to the channel layer.

(9)

The semiconductor device according to (8), in which the non-conductive section has a heat transfer section that includes a material having a thermal conductivity higher than a thermal conductivity of the channel layer.

(10)

The semiconductor device according to any one of (1) to (9), further including a back barrier layer that is provided in the channel layer and performs a quantum confinement on a two-dimensional electron gas to be formed in the channel layer.

(11)

A semiconductor device including:
a channel layer and a barrier layer provided in this order on a substrate; and
a plurality of gate electrodes, a plurality of source electrodes, and a plurality of drain electrodes that are formed on the substrate via the channel layer and the barrier layer and extend in a first direction, in which
the plurality of source electrodes and the plurality of drain electrodes are alternately arranged in a second direction intersecting the first direction,
the plurality of gate electrodes is arranged one by one between the source electrode and the drain electrode, and
the channel layer or the barrier layer has a plurality of non-conductive regions formed at positions opposed to the respective gate electrodes and arranged side by side, with a predetermined interval interposed therebetween, in an extending direction of the gate electrodes, the non-conductive regions inhibiting a current from flowing to the channel layer.
   (12)

The semiconductor device according to (11), in which the plurality of non-conductive regions is arranged at positions that are non-opposite to each other via the source electrode or the drain electrode.

(13)

The semiconductor device according to (11), in which the plurality of non-conductive regions is formed to be relatively wide in the first direction at a middle portion in the first direction of a region in which the plurality of non-conductive regions is formed, and is formed to be relatively narrow in the first direction at both end portions in the first direction of the region in which the plurality of non-conductive regions is formed.

The present application claims the benefit of Japanese Priority Patent Application JP2021-077976 filed with the Japan Patent Office on Apr. 30, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor device comprising:
a channel layer and a barrier layer provided in this order on a substrate; and
a gate electrode, a source electrode, and a drain electrode that are formed on the substrate via the channel layer and the barrier layer and extend in a first direction, wherein
the channel layer or the barrier layer has a plurality of non-conductive regions formed at positions opposed to the gate electrode and arranged side by side, with a predetermined interval interposed therebetween, in an extending direction of the gate electrode, the non-conductive regions inhibiting a current from flowing to the channel layer.

2. The semiconductor device according to claim 1, wherein
the channel layer has the non-conductive regions, and
the non-conductive regions are formed by ion implantation into the channel layer.

3. The semiconductor device according to claim 2, wherein
the channel layer has an element separation region in a region, of the channel layer, opposed to both end portions of the gate electrode, the source electrode, and the drain electrode in a plan view, and
the non-conductive regions and the element separation region are collectively formed in a same process in a manufacturing process.

4. The semiconductor device according to claim 2, further comprising a metal section that penetrates the non-conductive region and the barrier layer and is coupled to the source electrode.

5. The semiconductor device according to claim 1, wherein
the barrier layer has the non-conductive region, and
the barrier layer has, as the non-conductive region, an opening that penetrates the barrier layer.

6. The semiconductor device according to claim 5, wherein the gate electrode has a branch section that penetrates the channel layer through the opening.

7. The semiconductor device according to claim 6, wherein the branch section includes a material having a thermal conductivity higher than a thermal conductivity of the channel layer.

8. The semiconductor device according to claim 5, further comprising a non-conductive section that reaches the opening from a back surface of the substrate and inhibits the current from flowing to the channel layer.

9. The semiconductor device according to claim 8, wherein the non-conductive section has a heat transfer section that includes a material having a thermal conductivity higher than a thermal conductivity of the channel layer.

10. The semiconductor device according to claim 1, further comprising a back barrier layer that is provided in the channel layer and performs a quantum confinement on a two-dimensional electron gas to be formed in the channel layer.

11. A semiconductor device comprising:
a channel layer and a barrier layer provided in this order on a substrate; and
a plurality of gate electrodes, a plurality of source electrodes, and a plurality of drain electrodes that are formed on the substrate via the channel layer and the barrier layer and extend in a first direction, wherein
the plurality of source electrodes and the plurality of drain electrodes are alternately arranged in a second direction intersecting the first direction,
the plurality of gate electrodes is arranged one by one between the source electrode and the drain electrode, and
the channel layer or the barrier layer has a plurality of non-conductive regions formed at positions opposed to the respective gate electrodes and arranged side by side, with a predetermined interval interposed therebetween, in an extending direction of the gate electrodes, the non-conductive regions inhibiting a current from flowing to the channel layer.

12. The semiconductor device according to claim 11, wherein the plurality of non-conductive regions is arranged at positions that are non-opposite to each other via the source electrode or the drain electrode.

13. The semiconductor device according to claim 11, wherein the plurality of non-conductive regions is formed to be relatively wide in the first direction at a middle portion in the first direction of a region in which the plurality of non-conductive regions is formed, and is formed to be relatively narrow in the first direction at both end portions in the first direction of the region in which the plurality of non-conductive regions is formed.
